(19) United States
(12) Patent Application Publication
(10) Pub. No.: US 2026/0339222 A1
(43) Pub. Date: Oct. 29, 2026

(54) APPARATUS FOR SEMICONDUCTOR TECHNOLOGY

(71) Applicant: Carl Zeiss SMT GmbH, Oberkochen (DE)

(72) Inventor: Rusbeh GOECKE, Oberkochen (DE)

(21) Appl. No.: 19/654,200

(22) Filed: Apr. 21, 2026

(30) Foreign Application Priority Data
Apr. 23, 2025 (DE) 10 2025 115 585.2

(51) Int. Cl. G03F 7/00; H10P 72/00

(52) U.S. Cl. CPC G03F 7/70933; G03F 7/70525; G03F 7/70891; H10P 72/0402

(57) ABSTRACT

An apparatus for semiconductor technology comprising a closed system space in which a defined system atmosphere prevails and in which system components are arranged. The system space has at least one exchange opening which can be closed in a gas-tight manner for the exchange of at least one system component arranged in the system space. The exchange opening is surrounded by a purge device designed to form a flow curtain from purge gas flowing away from the system space of the apparatus. The purge gas is free of relevant contaminants to eliminate contaminations on a system component to be introduced through the exchange opening.

### CROSS-REFERENCE TO RELATED APPLICATION

This application claims benefit under 35 U.S.C. §119 to German Application No. 10 2025 115 585.2 filed Apr. 23, 2025. The entire disclosure of this application is incorporated by reference herein.

### FIELD

The disclosure relates to an apparatus for semiconductor technology, for example comprising a closed system space in which a defined system atmosphere prevails and in which system components are arranged.

### BACKGROUND

Some known apparatuses which are used to produce or test microstructured parts or the components used therefor are referred to as apparatuses for semiconductor technology. An example of such an apparatus is a photolithographic projection exposure apparatus.

Photolithography is used for producing microstructured parts, such as, e.g., integrated circuits. The projection exposure apparatus used in the process comprises an illumination system and a projection system. The image of a mask (also referred to as a reticle) illuminated by the illumination system is projected so as to reduce the size of the former onto a substrate, for example a silicon wafer, which is coated with a light-sensitive layer and arranged in the image plane of the projection system, using the projection system in order to transfer the mask structure to the light-sensitive coating of the substrate.

Irrespective of the wavelength used for the exposure of the substrate, it is often desirable for the region of the beam path from the radiation source through the illumination system, via the reticle and through the projection system as far as the substrate and also the optical elements participating in the beam path, such as mirrors or lens elements, to be kept as free of contaminations as reasonably possible in order to influence the beam path as little as reasonably possible. For this purpose, the components relevant to the beam path are generally arranged in a closed system space of the apparatus for semiconductor technology in such a way that the beam path from the radiation source as far as the substrate also runs completely within the system space. A defined system atmosphere typically prevails in the system space. The system atmosphere can be monitored and set by a control unit. However, the system atmosphere can be chosen such that the exposure radiation is not absorbed by the system atmosphere and also the least reasonably possible amount of undesired constituents is deposited at least on the optical surfaces of the optical elements.

In the case of EUV exposure radiation - i.e. exposure radiation having a wavelength of 5 nm to 30 nm, for example 13.5 nm - the system atmosphere may be, for example, a hydrogen atmosphere at extremely low pressure. In the case of DUV exposure radiation having a wavelength of e.g. 193 nm or 248 nm, the system atmosphere may also be air or nitrogen at ambient pressure, but it is desirable to regularly ensure that this atmosphere is free of contaminations. Very low air humidity can be used as well.

If - e.g., on account of optical degradation – it is desirable to exchange an element arranged in the system space, in certain known systems the system space is opened. Both as a result of the opening of the system space and as a result of the introduction of an exchange element, the atmosphere in the system space changes and contaminations may be introduced. In some known systems, therefore, after the exchange of an element, it is often desirable to carry out a relatively complex cleaning process, including a complete exchange of the system atmosphere.

### SUMMARY

The present disclosure seeks to provide an apparatus for semiconductor technology in which a relatively simplified exchange of an element arranged in the system space is possible.

In an aspect, the disclosure provides an apparatus for semiconductor technology comprising a closed system space, in which a defined system atmosphere prevails and in which system components are arranged, wherein the system space has at least one exchange opening which can be closed in a gas-tight manner for the exchange of at least one system component arranged in the system space, wherein the exchange opening is surrounded by a purge device designed to form a flow curtain from purge gas flowing away from the system space of the apparatus for the purpose of eliminating contaminations on a system component to be introduced through the exchange opening.

"Contaminations" as used herein are any foreign substances which, if they enter the system space, may adversely affect the operation of the apparatus for semiconductor technology. Contaminations may be, e.g., dust particles, but also molecules that absorb the exposure radiation or substances that adversely affect optical surfaces in the system space.

The disclosure has recognized that, even if strict clean room guidelines are observed in the environment of an apparatus for semiconductor technology, when a system component arranged in the system space with a defined system atmosphere is exchanged, the risk of contaminations being introduced during the actual exchange process, for example contaminations situated directly on the newly inserted system component, can be significantly reduced if the system component in question is cleaned with the aid of a purge gas directly before being introduced into the system space. The disclosure provides that the exchange opening through which the new system component is intended to be introduced and which is closed in a gas-tight manner during normal operation of the apparatus is surrounded by a purge device designed to form a flow curtain serving to eliminate possible contaminations on a system component to be introduced through the exchange opening. The flow curtain can be formed from a purge gas which itself is free of any contaminations relevant to the system atmosphere in regard to the system space. In other words, even if purge gas enters the system space, it is possible that no relevant contaminations are introduced as a result. Moreover, the purge gas in general can flow away from the system space of the apparatus, so that any foreign substances that the purge gas has possibly detached from the system component to be introduced can be carried away from the system space and thus cannot enter the latter.

It can be desirable for the purge device to be designed to generate a flow which is as laminar as reasonably possible around the system component to be introduced through the exchange opening. The laminar flow around the system component can result in transporting away foreign substances situated on the surface of the system component, but at the same time there is only a slight risk that foreign substances taken up from the system component will be deposited on the latter again or the foreign substances will enter the system space.

It may nevertheless be desirable for the purge device to be designed to introduce pressure surges of the purge gas for generating turbulence. As a result of the intermittent introduction of turbulence into the flow around the system component to be introduced, contaminations adhering thereto may possibly be detached better than from a laminar flow around. In general, it possible that a turbulent flow is always followed by a laminar flow around, in order to ensure the removal of any contaminations possibly loosely deposited on the system component to be introduced, during the turbulent flow around.

It is also possible for the purge device to be designed to at least intermittently cause increases in the temperature of the purge gas. As a result of the at least intermittent increase in temperature, diffusion processes away from the surface of the system component to be introduced into the laminar flow can be accelerated in order to then transport the contaminations away with the flow.

It can be desirable for the purge device to comprise guide surfaces for guiding the flow curtain in sections around a system component to be introduced. Corresponding guide surfaces can make it possible to ensure that the flow curtain sweeps over the system component to be introduced over as long a section as reasonably possible. Moreover, with a suitable design of the guide surfaces, in general a laminar flow can be ensured over a relatively long section. In addition, the guide surfaces can make it possible to ensure that no contaminations can be introduced into the flow curtain laterally from outside.

If guide surfaces are provided, the purge device can be designed to clean the guide surfaces by removing contaminations with the aid of purge gas before the exchange opening is opened. If cleaning the guide surfaces is carried out before the exchange opening is opened and, if appropriate, also before a system component to be introduced is brought into the region of the guide surfaces, any contaminations possibly present on the guide surfaces can be removed without the contaminations being able to reach the system space and/or the system component to be introduced. In this case, the space between the guide surfaces can also be purged, i.e. the possibly contaminated gas situated between the guide surfaces in the initial state is replaced by purge gas emerging from the purge device.

If the apparatus for semiconductor technology, as is typical, has a control unit for monitoring and setting the system atmosphere, the control unit can be designed to raise the pressure of the system atmosphere in the system space to a pressure higher than the ambient pressure before and/or during the opening of an exchange opening. If the pressure in the system space is correspondingly increased, a flow leading from the system space into the environment arises after the opening of an exchange opening. Such a flow can at least reduce the risk of contaminations entering the system space.

If it is desirable for the flow velocity of the purge gas to be controllable, a control unit can be provided, by which the flow velocity resulting from the purge gas and/or system atmosphere emerging from the exchange opening yields mass transfer Péclet numbers of greater than one, in each case relative to relevant contaminants and the length of the flow curtain. If the mass transfer Peclét number for a specific contamination is greater than one, it can be ensured that the mass transfer on account of the flow of the purge gas away from the system space is greater than any opposite mass transfer on account of diffusion. As a result, the risk of contamination of the system space on account of diffusion can be significantly reduced.

The purge gas introduced by the purge device can have a purity class comparable to class 0 according to ISO 8573-1:2010 and hence purer than class 1 according to ISO 8573-1:2010. Even if the purge gas need not necessarily be air, the aforementioned purity class nevertheless can help ensures in general that the purge gas itself is practically free of any possible contaminations.

It can be desirable for at least one exchange opening to be arranged and formed in such a way that the exchange path is one-dimensional for at least one system component to be exchanged through these exchange openings. An exchange path is deemed to be one-dimensional if a system component has to be guided exclusively along a rectilinear path for the exchange. If the exchange path is one-dimensional, the system component to be introduced can also be guided past the purge device along this path or the extension thereof. The purge device can then be optimized for this exchange path.

It can be desirable for a system component to be exchanged through the exchange opening to be optimized with regard to the flow around with purge gas of the flow curtain generated by the purge device. Depending on the design of the system component, in the initial state regions may arise which are not included on the part of the purge gas introduced by the purge device. Providing suitable flow channels and/or other design adaptations of the system component to be introduced enables corresponding regions to be reduced or even completely avoided.

### BRIEF DESCRIPTION OF THE DRAWINGS

The disclosure will now be described by way of example with reference to the accompanying drawings, in which:

FIG. 1 shows a schematic partial illustration of a first exemplary embodiment of an apparatus according to the disclosure for semiconductor technology;

FIG. 2 shows a schematic illustration of the apparatus according to FIG. 1 before the exchange opening is opened;

FIG. 3 shows a schematic illustration of the apparatus according to FIG. 1 during the introduction of a system component through the exchange opening; and

FIG. 4 shows an embodiment variant with respect to FIG. 3.

### DETAILED DESCRIPTION

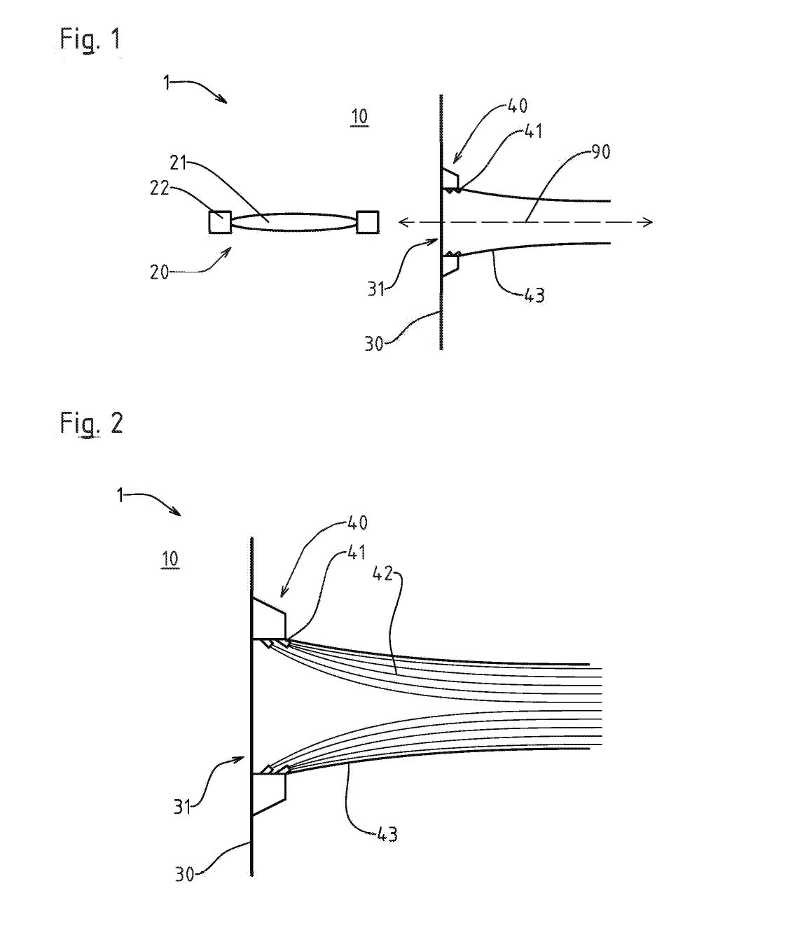

FIG. 1 schematically illustrates one exemplary embodiment of an apparatus 1 according to the disclosure for semiconductor technology, the illustration being limited to a part of the boundary wall 30 of a closed system space 10 of the apparatus 1. A defined system atmosphere prevails in the system space 10 of the apparatus 1 (to the left of the boundary wall 30), the system atmosphere being monitored and controlled by a control unit (not illustrated).

Various system components 20 of the apparatus 10 are arranged in the system space 10. In the illustrated part of the exemplary embodiment, the system component 20 is an optical element 21 for radiation transformation, e.g. a lens element or a mirror, which optical element is surrounded by a circumferential mount 22.

For the exchange of the system component 20, which may become desirable for example on account of optical degradation, an exchange opening 31 which can be closed in a gas-tight manner is provided in the boundary wall 30. The exchange opening 31 is in principle arranged in such a way that the system component 20 can be exchanged along a one-dimensional exchange path, which is indicated by the dashed double-headed arrow 90. In other words, the system component 20 to be exchanged which is situated in the system space 10 can be removed from the apparatus 1 by a rectilinear movement and a new system component 20 can be introduced into the system space 10 by a likewise rectilinear movement, albeit in the opposite direction.

In order to prevent contaminations from also entering the system space 10 together with the introduction of a new system component 20 into the system space, a purge device 40 is provided.

The purge device 40 surrounds the exchange opening 31 completely – i.e. thus also on the sides of the exchange opening 31 – and comprises gas outlets 41 pointing inwards but from the exchange opening 31 or the system space 10. A purge gas can be introduced via these gas outlets 41, and then forms a flow curtain 42 flowing away from the system space 10 of the apparatus 1 (cf. FIGS. 2-4). For shaping the flow curtain 42, guide surfaces 43 are provided, by which the flow curtain 42 is shaped at least for a length predefined by way of the guide surfaces 43, where a laminar flow is generally established.

FIG. 2 illustrates the flow curtain 42 formed from purge gas while the exchange opening 31 is still closed. In this state, the flow is completely laminar at least in the region of the guide surfaces 43, as a result of which contaminations, for example in the form of dust particles or molecules potentially contaminating the system space 10, which are situated on the inner side of the guide surfaces 43 are purged away from the guide surfaces 43 and/or from the space enclosed by the guide surfaces 43.

Once the guide surfaces 43 have been sufficiently cleaned of contaminations by the measure illustrated in FIG. 2, the exchange opening 31 can subsequently be opened. In this case, it is expedient, before the exchange opening 31 is actually opened, to increase and maintain the pressure in the interior of the system space 10 in such a way that there is an overpressure there relative to the environment of the apparatus 1. The same can correspondingly be accomplished via the control unit for controlling the system atmosphere. As a result, it is ensured that after the exchange opening 31 has been opened, a continuous gas flow from the system space 10 through the exchange opening 31 into the environment is established, by which at least an entry of dust particles or the like through the exchange opening 31 into the system space 10 can already be effectively avoided.

Furthermore, the flow velocity of the purge gas introduced through the gas outlets 41 is controlled by a control unit (not illustrated) in such a way that for the flow of the purge gas and the gas emerging from the system space 10, a flow velocity results for which a mass transfer Peclét number of greater than 1 is obtained in each case over the length predefined by the guide surfaces 43 and over contaminants previously identified as relevant. This ensures that any diffusion transport of relevant contaminants from the environment through the exchange opening 31 into the system space 10 is effectively reduced.

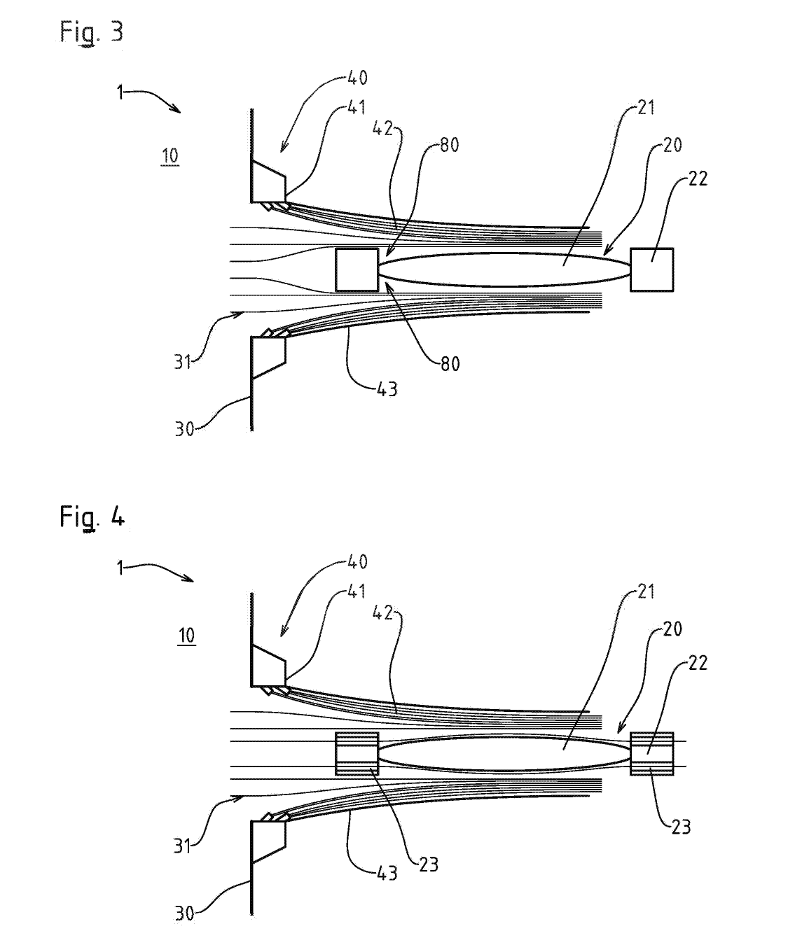

After the exchange opening 31 has been opened, the system components 20 to be exchanged can be removed from the system space 10 through the flow curtain 42, wherein a flow around the removed system component 20 is established, as is illustrated in FIG. 3 for the system component 20 to be subsequently inserted into the system space 10.

FIG. 3 illustrates how a new system component 20 is introduced through the exchange opening 31 along the exchange path 90 (cf. FIG. 1). In this case, the new system component 20 is guided through the flow curtain 42 formed between the guide surfaces 43, which flow curtain is composed of purge gas and is supplemented by the gas flow 44 from the system space 10 into the environment. On account of the guide surfaces 43, a substantially laminar flow around the system component 20 results, by which any contaminations possibly situated on the system component 20 can and ought to be removed – namely purged away.

Both for cleaning the guide surfaces 43 and when introducing a system component 20, it can be helpful to intermittently generate turbulence in the flow curtain 42. For this purpose, provision can be made for the purge device 40 to be designed for introducing pressure surges into the purge gas. In any case, however, provision should be made for a period of time with a turbulent flow of the purge gas to be followed by a period of time with a laminar flow in order to remove any contaminations deposited on account of the turbulence from the guide surfaces 43 and/or the system component 20 to be introduced.

The exemplary embodiment according to FIG. 3 reveals regions 80 on the system component 20 into which a laminar flow, as illustrated, does not penetrate. As a result, undesired contaminations may remain in precisely these regions 80 and may be introduced into the system space 10 together with the system component 20.

In order to address this risk, in the embodiment variant according to FIG. 4, the system component 20 to be introduced is itself optimized with regard to the flow of the purge gas around it. In this regard, flow channels 23 are introduced in the mount 22 of the optical element 21, through which flow channels the purge gas or gas emerging from the system space 10 on account of an overpressure relative to the environment can flow in order that gas can flow even over otherwise hard-to-reach locations and contaminations can thus be eliminated therefrom.

In all exemplary embodiments, the purge gas can have a purity class comparable to class 0 defined for air in ISO 8573-1:2010, i.e. purge gas itself has practically no contaminations and practically no moisture either.

What is claimed is:

1. An apparatus, comprising:
a wall partially defining a space configured to have a defined atmosphere; and
an exchange opening in the wall; and
a purge device surrounding the exchange opening,
wherein:
in a first configuration, the exchange opening is closed in a gas-tight manner;
in a second configuration, the exchange opening is open to allow a system component to pass through the exchange opening and into the space; and
the purge device configured to form a flow curtain of a purge gas flowing away from the space to eliminate contaminants on the system component when the system component passes through the exchange opening and into the space.

2. The apparatus of claim 1, wherein the purge device is configured to form a laminar flow of the purge gas around the system component when the system component passes through the exchange opening and into the space.

3. The apparatus of claim 1, wherein the purge device is configured to pressure surges of the purge gas to generate turbulent flow of the purge gas.

4. The apparatus of claim 1, wherein the purge device is configured to intermittently increase a temperature of the purge gas.

5. The apparatus of claim 1, wherein the purge device comprises guide surfaces configured to guide the flow curtain around sections of the system component when the system component passes through the exchange opening and into the space.

6. The apparatus of claim 5, wherein the purge device is configured to use the purge gas to remove contaminants from the guide surfaces.

7. The apparatus of claim 1, further comprising a control unit configured to monitor and set the defined atmosphere in the space, wherein the control unit is configured to raise a pressure of the defined atmosphere in the system space to a pressure greater than an ambient pressure.

8. The apparatus of claim 7, wherein the control unit is configured to control a flow velocity of the purge gas is controllable so that the purge gas and/or an atmosphere emerging from the exchange opening yields mass transfer Péclet numbers of greater than 1, in each case relative to relevant contaminants and the length of the flow curtain.

9. The apparatus of claim 1, wherein system is configured to that a flow velocity of the purge gas is controllable so that the purge gas and/or an atmosphere emerging from the exchange opening yields mass transfer Péclet numbers of greater than 1, in each case relative to relevant contaminants and the length of the flow curtain.

10. The apparatus of claim 1, wherein the purge gas introduced has a purity class that is purer than class 1 according to ISO 8573-1:2010.

11. The apparatus of claim 1, wherein the exchange opening is configured so that an exchange path for the system component is one dimensional.

12. The apparatus of claim 1, wherein the system component optimized with regard to the flow around with purge gas of the flow curtain generated by the purge device.

13. The apparatus of claim 1, wherein the purge device is configured to form a laminar flow of the purge gas around the system component when the system component passes through the exchange opening and into the space, and the purge device is configured to pressure surges of the purge gas to generate turbulent flow of the purge gas.

14. The apparatus of claim 1, wherein the purge device is configured to form a laminar flow of the purge gas around the system component when the system component passes through the exchange opening and into the space, and the purge device is configured to intermittently increase a temperature of the purge gas.

15. The apparatus of claim 1, wherein the purge device is configured to form a laminar flow of the purge gas around the system component when the system component passes through the exchange opening and into the space, and the purge device comprises guide surfaces configured to guide the flow curtain around sections of the system component when the system component passes through the exchange opening and into the space.

16. The apparatus of claim 1, further comprising a control unit configured to monitor and set the defined atmosphere in the space, wherein the control unit is configured to raise a pressure of the defined atmosphere in the system space to a pressure greater than an ambient pressure, wherein the purge device is configured to form a laminar flow of the purge gas around the system component when the system component passes through the exchange opening and into the space.

17. The apparatus of claim 1, wherein the apparatus is a semiconductor apparatus.

18. The apparatus of claim 1, wherein the apparatus is a photolithographic projection exposure apparatus comprising an illumination system and a projection system, and the system component is an optical element.

19. The apparatus of claim 18, further comprising a mask and a wafer, wherein the illumination system is configured to illuminate the mask, and the projection system is configured to image the illuminated mask onto the wafer.

20. An apparatus for semiconductor technology comprising a closed system space in which a defined system atmosphere prevails and in which system components are arranged, wherein the system space comprises at least one exchange opening which can be closed in a gas-tight manner for the exchange of at least one system component arranged in the system space, and wherein the exchange opening is surrounded by a purge device designed to form a flow curtain from purge gas flowing away from the system space of the apparatus for the purpose of eliminating contaminations on a system component to be introduced through the exchange opening.
